(19) United States
(12) Patent Application Publication
(10) Pub. No.: US 2024/0387784 A1
(43) Pub. Date: Nov. 21, 2024

(54) METHOD FOR PRODUCING SEMICONDUCTOR NANOPARTICLES, SEMICONDUCTOR NANOPARTICLES, AND LIGHT-EMITTING DEVICE

(71) Applicants: NATIONAL UNIVERSITY CORPORATION TOKAI NATIONAL HIGHER EDUCATION AND RESEARCH SYSTEM, Nagoya-shi (JP); OSAKA UNIVERSITY, Suita-shi (JP); NICHIA CORPORATION, Anan-shi (JP)

(72) Inventors: Tsukasa TORIMOTO, Nagoya-shi (JP); Tatsuya KAMEYAMA, Nagoya-shi (JP); Susumu KUWABATA, Suita-shi (JP); Taro UEMATSU, Suita-shi (JP); Tomoya KUBO, Tokushima-shi (JP); Yohei IKAGAWA, Naruto-shi (JP); Daisuke OYAMATSU, Tokushima-shi (JP)

(73) Assignees: NATIONAL UNIVERSITY CORPORATION TOKAI NATIONAL HIGHER EDUCATION AND RESEARCH SYSTEM, Nagoya-shi (JP); OSAKA UNIVERSITY, Suita-shi (JP); NICHIA CORPORATION, Anan-shi (JP)

(21) Appl. No.: 18/294,524

(22) PCT Filed: Jul. 8, 2022
(86) PCT No.: PCT/JP2022/027039

§ 371 Date: Feb. 1, 2024

(30) Foreign Application Priority Data
Aug. 2, 2021 (JP) 2021-126859

(51) Int. Cl. H01L 33/50; C01G 15/00; C09K 11/62

(52) U.S. Cl. CPC H01L 33/502; C01G 15/00; C09K 11/62

(57) ABSTRACT

Provided is an efficient method for producing semiconductor nanoparticles that exhibit band edge emission. The method comprises performing a first heat treatment of a first mixture, which contains a Cu salt, a Ag salt, a salt containing at least one of In or Ga, a gallium halide, and an organic solvent, to obtain first semiconductor nanoparticles. At least one of the Cu salt, the Ag salt, or the salt containing at least one of In or Ga in the first mixture contains a compound having a bond formed of a metal and sulfur.

### TECHNICAL FIELD

The present disclosure relates to a method of producing semiconductor nanoparticles, semiconductor nanoparticles, and light emitting device.

### BACKGROUND ART

Semiconductor particles having a particle size of, for example, 10 nm or smaller are known to exhibit a quantum size effect, and such nanoparticles are referred to as “quantum dots” (also referred to as “semiconductor quantum dots”). The “quantum size effect” refers to a phenomenon in which a valence band and a conduction band that are each regarded as continuous in bulk particles become discrete when the particle size is on the nanoscale and the band-gap energy varies with the particle size.

Quantum dots are capable of absorbing light and converting the wavelength into a light corresponding to their band-gap energy; therefore, white light emitting devices utilizing emission of such quantum dots have been proposed (see, for example, Japanese Laid-Open Patent Publication Nos. 2012-212862 and 2010-177656). In addition, wavelength conversion films containing core-shell-structured semiconductor quantum dots that can exhibit band-edge emission and have a low-toxicity composition have been proposed (see, for example, WO 2014/129067). Further, sulfide nanoparticles have been studied as ternary semiconductor nanoparticles that can exhibit band-edge emission and have a low-toxicity composition, (see, for example, WO 2018/159699, WO 2019/160094, and WO 2020/162622).

### SUMMARY OF INVENTION

### Technical Problem

WO 2018/159699 discloses an efficient production method for obtaining semiconductor nanoparticles exhibiting band-edge emission by one-pot synthesis; however, there is room for further improvement in terms of the band-edge emission purity of the resulting semiconductor nanoparticles. Further, WO 2019/160094 and WO 2020/162622 disclose semiconductor nanoparticles exhibiting a high band-edge emission purity; however, there is room for further improvement in terms of efficient production method.

An object of an embodiment of the present disclosure is to provide a method of efficiently producing semiconductor nanoparticles that exhibit band-edge emission.

### Solution to Problem

A first embodiment is a method of producing semiconductor nanoparticles, the method including performing a first heat treatment of a first mixture, which contains a copper (Cu) salt, a silver (Ag) salt, a salt containing at least one of indium (In) or gallium (Ga), a gallium halide, and an organic solvent, to obtain first semiconductor nanoparticles, wherein at least one of the Cu salt, the Ag salt, or the salt containing at least one of In or Ga in the first mixture contains a compound having a bond formed of a metal and sulfur (S).

A second embodiment is semiconductor nanoparticles including a first semiconductor that comprises copper (Cu), silver (Ag), indium (In), gallium (Ga), and sulfur (S). In the surfaces of the semiconductor nanoparticles, a second semiconductor that contains Ga and S but does not substantially contain Ag is arranged. The semiconductor nanoparticles exhibit band-edge emission with a peak emission wavelength in a wavelength range of 600 nm to 680 nm when irradiated with a light having a wavelength of 365 nm, the band-edge emission purity is 60% or higher, and the internal quantum yield of the band-edge emission is 15% or more.

A third embodiment is a light emitting device including: a light conversion member containing the above-described semiconductor nanoparticles; and a semiconductor light emitting element.

### Advantageous Effects of Invention

According to an embodiment of the present disclosure, a method of efficiently producing semiconductor nanoparticles that exhibit band-edge emission may be provided.

### BRIEF DESCRIPTION OF DRAWINGS

FIG. 1 shows an exemplary emission spectrum for the semiconductor nanoparticles of Examples and Comparative Example.

### DESCRIPTION OF EMBODIMENTS

The term “step” used herein encompasses not only a discrete step but also a step that cannot be clearly distinguished from other steps, as long as the intended purpose of the step is achieved. When there are plural substances that correspond to a component of a composition, an indicated amount of the component contained in the composition means, unless otherwise specified, a total amount of the plural substances existing in the composition. Further, as an upper limit and a lower limit of a numerical range described in the present specification, the values exemplified for the numerical range can be arbitrarily selected and combined. The full width at half maximum in an emission spectrum means a wavelength width (full width at half maximum: FWHM) of an emission spectrum at which the emission intensity becomes 50% of the maximum emission intensity in the emission spectrum. In this description, a relationship between a color name and a chromaticity coordinate, a relationship between a wavelength range of light and a color name of monochromatic light, etc. comply with JIS Z8110. Embodiments of the present invention will now be described in detail. It is noted here, however, that the below-described embodiments are merely examples of semiconductor nanoparticles, a method of producing thereof, and light emitting device that embody the technical idea of the present invention, and the present invention is not limited to the below-described semiconductor nanoparticles, method of producing thereof, and light emitting device.

### Method of Producing Semiconductor Nanoparticles

The method of producing semiconductor nanoparticles includes a first step of performing a first heat treatment of a first mixture, which contains a copper (Cu) salt, a silver (Ag) salt, a salt containing at least one of indium (In) or gallium (Ga), a gallium halide, and an organic solvent, to obtain first semiconductor nanoparticles. In the first mixture, at least one of the Cu salt, the Ag salt, or the salt containing at least one of In or Ga contains a compound having a bond formed of the metal constituting the respective salt and sulfur (S). As required, the method of producing semiconductor nanoparticles may further include other steps in addition to the first step.

### First Step

The first step may include: a first mixing step of obtaining a first mixture that contains a Cu salt, a Ag salt, a salt containing at least one of In or Ga (hereinafter, may be simply referred to as “(In,Ga) salt”), a gallium halide, and an organic solvent; and a first heat treatment step of performing a first heat treatment of the thus obtained first mixture to obtain first semiconductor nanoparticles. At least one of the Cu salt, the Ag salt, or the (In,Ga) salt in the first mixture may also serve as a sulfur (S) source, and may contain a compound having a bond formed of the metal constituting the respective salt and sulfur (S).

By allowing a gallium halide to exist during the synthesis of the first semiconductor nanoparticles, it is made easy to control the particle size of the resulting first semiconductor nanoparticles. It is believed that, as a result, semiconductor nanoparticles that exhibit band-edge emission with a high purity can be efficiently produced by one-pot synthesis.

In the first mixing step, a first mixture is prepared by mixing a Cu salt, a Ag salt, a (In,Ga) salt, a gallium halide, and an organic solvent. A mixing method in the first mixing step may be selected as appropriate from those mixing methods that are normally employed.

The Cu salt, the Ag salt, and the (In,Ga) salt in the first mixture may each be either an organic acid salt or an inorganic acid salt. Specifically, examples of the inorganic acid salt include nitrates, sulfates, hydrochlorides, and sulfonates, and examples of the organic acid salt include formates, acetates, oxalates, and acetylacetonates. The Cu salt, the Ag salt, and the (In,Ga) salt may each be preferably at least one selected from the group consisting of these acid salts, and the Cu salt, the Ag salt, and the (In,Ga) salt may each be more preferably at least one selected from the group consisting of organic acid salts such as acetates and acetylacetonates because these salts are highly soluble in organic solvents and thus allow reaction to proceed more uniformly. The first mixture may contain each of the Cu salt, the Ag salt, and the (In,Ga) salt singly, or a combination of two or more of each of these salts. Further, the salt containing at least one of In or Ga in the first mixture may be a salt that contains at least one selected from the group consisting of an In salt and a Ga salt, or a salt that contains at least one Ga salt and further contains at least one In salt. Moreover, at least one of the Cu salt, the Ag salt, the In salt, or the Ga salt in the first mixture may contain a compound having a bond formed of the metal constituting the respective salt and sulfur (S) (e.g., a compound having a Cu—S bond in the case of the Cu salt).

The Cu salt in the first mixture may contain a compound having a Cu—S bond. The Cu—S bond may be any of a covalent bond, an ionic bond, a coordinate bond, and the like. Examples of the compound having a Cu—S bond include Cu salts of sulfur-containing compounds, and the compound having a Cu—S bond may be a sulfur-containing organic acid salt, a sulfur-containing inorganic acid salt, a sulfur-containing organic metal compound, or the like of Cu. Examples of the sulfur-containing compounds include thiocarbamic acids, dithiocarbamic acids, thiocarbonic acids, dithiocarbonic acids (xanthic acid), trithiocarbonic acids, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds include aliphatic thiocarbamic acids, aliphatic dithiocarbamic acids, aliphatic thiocarbonic acids, aliphatic dithiocarbonic acids, aliphatic trithiocarbonic acids, aliphatic thiocarboxylic acids, and aliphatic dithiocarboxylic acids. Examples of the aliphatic groups in these sulfur-containing compounds include alkyl groups and alkenyl groups that have from 1 to 12 carbon atoms. The aliphatic thiocarbamic acids may include dialkylthiocarbamic acids, and the aliphatic dithiocarbamic acids may include dialkyldithiocarbamic acids. In dialkylthiocarbamic acids and dialkyldithiocarbamic acids, the alkyl group may have from 1 to 12 carbon atoms, preferably from 1 to 4 carbon atoms. In dialkylthiocarbamic acids and dialkyldithiocarbamic acids, two alkyl groups may be the same or different. Specific examples of a compound having a Cu—S bond include copper (I) ethylxanthate (Cu(EX)) as monovalent copper compound, and copper (II) dimethyldithiocarbamate, copper (II) diethyldithiocarbamate (Cu(DDTC)₂), copper (II) ethylxanthate (Cu(EX)₂) as divalent copper compound. The first mixture may contain the compound having a Cu—S bond singly, or in combination of two or more thereof.

The Ag salt in the first mixture may contain a compound having an Ag—S bond because silver sulfide by-product may be suppressed in the first heat treatment step described below. The Ag—S bond may be any of a covalent bond, an ionic bond, a coordinate bond, and the like. Examples of the compound having an Ag—S bond include Ag salts of sulfur-containing compounds, and the compound having an Ag—S bond may be a sulfur-containing organic acid salt, a sulfur-containing inorganic acid salt, a sulfur-containing organic metal compound, or the like of Ag. Examples of the sulfur-containing compounds include thiocarbamic acids, dithiocarbamic acids, thiocarbonic acids, dithiocarbonic acids (xanthic acid), trithiocarbonic acids, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds are the same as described above. Specific examples of a compound having an Ag—S bond include silver dimethyldithiocarbamate, silver diethyldithiocarbamate (Ag (DDTC)), silver ethylxanthate (Ag(EX)). The first mixture may contain the compound having an Ag—S bond singly, or in combination of two or more thereof.

The In salt in the first mixture may contain a compound having an In—S bond. The In—S bond may be any of a covalent bond, an ionic bond, a coordinate bond, and the like. Examples of the compound having an In—S bond include In salts of sulfur-containing compounds, and the compound having an In—S bond may be a sulfur-containing organic acid salt, a sulfur-containing inorganic acid salt, a sulfur-containing organic metal compound, or the like of In. Examples of the sulfur-containing compounds include thiocarbamic acids, dithiocarbamic acids, thiocarbonic acids, dithiocarbonic acids (xanthic acid), trithiocarbonic acids, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds are the same as described above. Specific examples of a compound having an In—S bond include indium tris(dimethyldithiocarbamate), indium tris(diethyldithiocarbamate) (In(DDTC)₃), indium chloro-bis(diethyldithiocarbamate), and indium ethylxanthate (In(EX)₃). The first mixture may contain the compound having an In—S bond singly, or in combination of two or more thereof.

The Ga salt in the first mixture may contain a compound having a Ga—S bond. The Ga—S bond may be any of a covalent bond, an ionic bond, a coordinate bond, and the like. Examples of the compound having a Ga—S bond include Ga salts of sulfur-containing compounds, and the compound having a Ga—S bond may be a sulfur-containing organic acid salt, a sulfur-containing inorganic acid salt, a sulfur-containing organic metal compound, or the like of Ga. Examples of the sulfur-containing compounds include thiocarbamic acids, dithiocarbamic acids, thiocarbonic acids, dithiocarbonic acids (xanthic acid), trithiocarbonic acids, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds are the same as described above. Specific examples of a compound having a Ga—S bond include gallium tris(dimethyldithiocarbamate), gallium tris(diethyldithiocarbamate) (Ga (DDTC)₃), gallium chloro-bis(diethyldithiocarbamate), and gallium ethylxanthate (Ga (EX)₃). The first mixture may contain the compound having a Ga—S bond singly, or in combination of two or more thereof.

Examples of the gallium halide in the first mixture include gallium fluoride, gallium chloride, gallium bromide, and gallium iodide. The gallium halide may contain at least one selected from the group consisting of these halides. Further, the gallium halide may contain at least gallium chloride. These gallium halides may be used singly, or in combination of two or more thereof.

Examples of the organic solvent in the first mixture include: amines containing a hydrocarbon group having from 4 to 20 carbon atoms, such as alkylamines and alkenylamines having from 4 to 20 carbon atoms; thiols containing a hydrocarbon group having from 4 to 20 carbon atoms, such as alkylthiols and alkenylthiols having from 4 to 20 carbon atoms; and phosphines containing a hydrocarbon group having from 4 to 20 carbon atoms, such as alkylphosphines and alkenylphosphines having from 4 to 20 carbon atoms, and the first mixture preferably contains at least one selected from the group consisting of these organic solvents. These organic solvents may, for example, eventually modify the surfaces of the resulting first semiconductor nanoparticles. These organic solvents may be used in combination of two or more thereof and, for example, a mixed solvent of a combination of at least one selected from thiols containing a hydrocarbon group having from 4 to 20 carbon atoms and at least one selected from amines containing a hydrocarbon group having from 4 to 20 carbon atoms may be used. These organic solvents may also be used as a mixture with other organic solvent. When the organic solvent contains any of the above-described thiols and any of the above-described amines, a content volume ratio of the thiol with respect to the amine (thiol/amine) is, for example, higher than 0 but 1 or lower, preferably from 0.007 to 0.2.

A content ratio of Cu, Ag, In, Ga, and S in the first mixture may be selected as appropriate in accordance with the intended composition. In this case, the content ratio of Cu, Ag, In, Ga, and S does not have to conform to a stoichiometric ratio. For example, a ratio (Ga/(In+Ga)) of the number of moles of Ga with respect to a total number of moles of In and Ga may be 0.2 to 0.95, 0.4 to 0.9, or 0.6 to 0.9. In addition, for example, a ratio (Cu/(Cu+Ag+In+Ga)) of the number of moles of Cu with respect to a total number of moles of Cu, Ag, In, and Ga may be 0.01 to 0.5. Further, for example, a ratio (Cu/(Cu+Ag)) of the number of moles of Cu with respect to a total number of moles of Cu and Ag may be 0.05 or higher but lower than 1.0. Still further, for example, a ratio (Ag/(Cu+Ag+In+Ga)) of the number of moles of Ag with respect to a total number of moles of Cu, Ag, In, and Ga may be 0.05 to 0.55. Yet still further, for example, a ratio ((Cu+Ag)/(Cu+Ag+In+Ga)) of a total number of moles of Cu and Ag with respect to a total number of moles of Cu, Ag, In, and Ga may be 0.01 to 1.2. Moreover, for example, a ratio (S/(Cu+Ag+In+Ga)) of the number of moles of S with respect to a total number of moles of Cu, Ag, In, and Ga may be 0.4 to 1.6.

The first mixture may further contain an alkali metal salt. Examples of the alkali metal (hereinafter, may be simply referred to as “M^{a}”) include lithium (Li), sodium (Na), potassium (K), rubidium (Rb), and cesium (Cs). The alkali metal may preferably contain at least Li because Li has an ionic radius close to that of Ag. Examples of the alkali metal salt include organic acid salts and inorganic acid salts. Specifically, examples of the inorganic acid salts include nitrates, sulfates, hydrochlorides, and sulfonates, and examples of the organic acid salts include acetates and acetylacetonates. Thereamong, organic acid salts are preferred because they are highly soluble in organic solvents.

When the first mixture contains an alkali metal salt, a ratio (M^{a}/(Ag+Cu+M^{a})) of the number of alkali metal (M^{a}) with respect to a total number of Ag, Cu and alkali metal (M^{a}) may be, for example, lower than 1, and it is preferably 0.8 or lower, more preferably 0.4 or lower, still more preferably 0.2 or lower. Further, this ratio may be, for example, higher than 0, and it is preferably 0.05 or higher, more preferably 0.1 or higher.

In the first mixture, a ratio of the molar content of Ga contained in the gallium halide with respect to a total molar amount of Ag and Cu that are contained in the Ag salt and the Cu salt may be, for example, 0.01 to 1 and, from the viewpoint of internal quantum yield, it may be preferably 0.10 or higher, or 0.45 or lower.

In the first mixture, a total molar concentration of Ag and Cu that are contained in the Ag salt and the Cu salt may be, for example, 0.001 mmol/L to 500 mmol/L and, from the viewpoint of internal quantum yield, it may be preferably 0.002 mmol/L or higher, or 100 mmol/L or lower, more preferably 0.005 mmol/L or higher, or 10 mmol/L or lower.

In the first heat treatment step, a first heat treatment of the first mixture is performed to obtain first semiconductor nanoparticles. The temperature of the first heat treatment may be, for example, from 200° C. to 320° C. The first heat treatment step may include: a temperature raising step of raising the temperature of the first mixture to a temperature in a range of from 200° C. to 320° C.; and a synthesis step of performing a heat treatment of the first mixture at a temperature in a range of from 200° C. to 320° C. for a prescribed time.

The range to which the temperature is raised in the temperature raising step of the first heat treatment step is preferably from 200° C. to 320° C., more preferably 230° C. or higher, or 290° C. or lower. A temperature increase rate may be adjusted such that the highest temperature during the temperature raising does not exceed the intended temperature, and it is, for example, from 1° C./min to 50° C./min.

The temperature of the heat treatment in the synthesis step of the first heat treatment step is preferably from 200° C. to 320° C., more preferably 230° C. or higher, or 290° C. or lower. The duration of the first heat treatment in the synthesis step may be, for example, 3 seconds or longer, and it is preferably 1 minute or longer, 10 minutes or longer, 30 minutes or longer, 60 minutes or longer, 90 minutes or longer. Further, the duration of the first heat treatment may be, for example, 300 minutes or shorter, preferably 270 minutes or shorter, 240 minutes or shorter. The duration of the first heat treatment in the synthesis step is defined that it starts at the time when the temperature reaches a temperature set in the above-described range (e.g., at the time when the temperature reaches 250° C. in a case where the set temperature is 250° C.), and ends at the time when an operation for lowering the temperature is carried out. By the synthesis step, a dispersion containing the first semiconductor nanoparticles may be obtained.

The atmosphere of the first heat treatment step is preferably an inert gas atmosphere, particularly an argon atmosphere or a nitrogen atmosphere. By using an inert gas atmosphere, the generation of an oxide as a by-product as well as the oxidation of the surfaces of the resulting first semiconductor nanoparticles may be reduced or prevented. In the inert gas atmosphere, a content of inert gas may be, for example, 90% by volume or more, preferably 95% by volume or more, or 98% gy volume or more.

The method of producing semiconductor nanoparticles may include, after the above-described synthesis step, the cooling step of lowering the temperature of a dispersion containing the resulting first semiconductor nanoparticles. The cooling step starts at the time when an operation for lowering the temperature is carried out, and ends at the time when the dispersion is cooled to 50° C. or lower.

From the viewpoint of inhibiting the generation of silver sulfide from unreacted Ag salt, the cooling step preferably includes a period in which the temperature lowering rate is 50° C./min or higher. The temperature lowering rate is preferably 50° C./min or higher particularly at the time when the temperature starts to decrease after the operation for lowering the temperature is carried out.

The atmosphere of the cooling step is preferably an inert gas atmosphere, particularly an argon atmosphere or a nitrogen atmosphere. By using an inert gas atmosphere, the generation of an oxide as a by-product as well as the oxidation of the surfaces of the resulting first semiconductor nanoparticles may be reduced or prevented.

The method of producing semiconductor nanoparticles may also include a separation step of separating the first semiconductor nanoparticles from the dispersion, and may further include a purification step as required. In the separation step, for example, the dispersion containing the first semiconductor nanoparticles may be centrifuged to recover the resulting supernatant containing the first semiconductor nanoparticles. In the purification step, for example, an appropriate organic solvent such as an alcohol may be added to the supernatant obtained in the separation step, and the resultant may be subsequently centrifuged to recover the first semiconductor nanoparticles as a precipitate. The first semiconductor nanoparticles may also be recovered by vaporizing the organic solvent from the supernatant. The thus recovered precipitate may be dried by, for example, vacuum degassing, air drying, or a combination of vacuum degassing and air drying. The air drying may be performed by, for example, leaving the precipitate in the atmosphere at normal temperature and normal pressure and, in this case, the precipitate may be left to stand for 20 hours or longer, for example, about 30 hours. Further, the recovered precipitate may be dispersed in an appropriate organic solvent.

In the method of producing semiconductor nanoparticles, the purification step that includes addition of an organic solvent such as an alcohol and centrifugation may be performed multiple times as required. As the alcohol used for purification, a lower alcohol having 1 to 4 carbon atoms such as methanol, ethanol, n-propyl alcohol, or isopropyl alcohol may be used. When the precipitate is dispersed in an organic solvent, for example, a halogen-based solvent such as chloroform, dichloromethane, dichloroethane, trichloroethane, or tetrachloroethane, or a hydrocarbon-based solvent such as toluene, cyclohexane, hexane, pentane, or octane may be used as the organic solvent. From the viewpoint of internal quantum yield, the organic solvent used for dispersing the precipitate may be a halogen-based solvent.

The first semiconductor nanoparticles obtained in the above-described manner may be in the state of a dispersion or a dry powder. The first semiconductor nanoparticles may exhibit band-edge emission and may exhibit high band-edge emission purity. The semiconductor nanoparticles obtained by the method of producing semiconductor nanoparticles may be the first semiconductor nanoparticles described above, or may be the second semiconductor nanoparticles obtained after the second step described below.

The method of producing semiconductor nanoparticles may further include a second step of performing a second heat treatment of a second mixture containing the first semiconductor nanoparticles and gallium halide to obtain second semiconductor nanoparticles.

### Second Step

The second step may include: the second mixing step of obtaining a second mixture that contains the first semiconductor nanoparticles obtained in the above-described first step and a gallium halide; and the second heat treatment step of performing a second heat treatment of the thus obtained second mixture to obtain second semiconductor nanoparticles.

By performing the second heat treatment of the second mixture that contains the first semiconductor nanoparticles and a gallium halide, second semiconductor nanoparticles in which the band-edge emission purity and the internal quantum yield are further improved can be produced. The reasons for this are believed, for example, as follows.

Ga defects (e.g., Ga-deficient parts) of a semiconductor containing Ga and S (e.g., GaSₓ; x is, for example, 0.8 to 1.5) may exist on the surfaces of the first semiconductor nanoparticles. It is thought that the Ga moiety of the gallium halide reacts with the Ga defects to fill the Ga defects, and further reacts with S atoms existing in the reaction system. It may be thought that, as a result, the concentration of Ga and S in the vicinity of the Ga defects is increased and the Ga defects are compensated, whereby the band-edge emission purity and the internal quantum yield are improved.

It may be also thought that the Ga atom of the gallium halide is coordinated to the S atoms on the surface of the semiconductor containing Ga and S which exists on the surfaces of the first semiconductor nanoparticles, and that the halogen atom of the thus coordinated gallium halide reacts with S components existing in the reaction system. It may be thought that, as a result, the concentration of Ga and S in the vicinity of the surfaces is increased and the remaining surface defects are reduced, whereby the band-edge emission purity and the internal quantum yield are improved.

Further, it may be also thought that, when a compound having a Cu—S bond (e.g., copper (I) ethylxanthate: Cu(EX)) is used as a raw material of the first semiconductor nanoparticles, a sulfur-containing compound (e.g., xanthic acid) partially remains in the resulting first semiconductor nanoparticles, and that the gallium halide acts on those parts of the partially remaining sulfur-containing compound to facilitate the conversion thereof into GaSₓ. It may be thought that, as a result, the concentration of Ga and S in the vicinity of the surfaces is increased and the remaining surface defects are reduced, whereby the band-edge emission purity and the internal quantum yield are improved.

In the second mixing step, a second mixture is obtained by mixing the first semiconductor nanoparticles, the compound containing a Group 13 element and gallium halide. The second mixture may further contain an organic solvent. The organic solvent contained in the second mixture is the same as the organic solvent exemplified in the first step above. When the second mixture contains an organic solvent, the second mixture may be prepared such that the concentration of the first semiconductor nanoparticles therein is, for example, from 5.0×10⁻⁷ mol/L to 5.0×10⁻⁵ mol/L, particularly from 1.0×10⁻⁶ mol/L to 1.0×10⁻⁵ mol/L. It is noted here that the concentration of the first semiconductor nanoparticles is set based on the amount of substance as particles. The “amount of substance as particles” refers to a molar amount assuming a single particle as a huge molecule, and is equal to a value obtained by dividing the number of the nanoparticles contained in a dispersion by Avogadro constant (NA=6.022×10²³).

Examples of the gallium halide in the second mixture include gallium fluoride, gallium chloride, gallium bromide, and gallium iodide. The gallium halide may contain at least one selected from the group consisting of these halides. Further, the gallium halide may contain at least gallium chloride. These gallium halides may be used singly, or in combination of two or more thereof.

In the second mixture, a content molar ratio of the gallium halide with respect to the first semiconductor nanoparticles may be, for example, 0.01 to 50, preferably 0.1 or higher, or 10 or lower.

In the second heat treatment step, a second heat treatment of the second mixture is performed to obtain second semiconductor nanoparticles. The temperature of the second heat treatment may be, for example, 200° C. to 320° C. The second heat treatment step may include: the temperature raising step of raising the temperature of the second mixture to a temperature in a range of 200° C. to 320° C.; and the modification step of performing a heat treatment of the second mixture by maintaining a heat treatment temperature in a range of 200° C. to 320° C. for a prescribed time.

The second heat treatment step may further include, prior to the temperature raising step, the pre-heat treatment step of performing a heat treatment of the second mixture at a temperature of from 60° C. to 100° C. The temperature of the heat treatment in the pre-heat treatment step may be, for example, from 70° C. or higher, or 90° C. or lower. The duration of the heat treatment in the pre-heat treatment step may be, for example, from 1 minute to 30 minutes, preferably 5 minutes or longer, or 20 minutes or shorter.

The range to which the temperature is raised in the temperature raising step of the second heat treatment step may be from 200° C. to 320° C., preferably 230° C. or higher, or 290° C. or lower. A temperature increase rate may be adjusted such that the highest temperature during the temperature raising does not exceed the intended temperature, and it is, for example, from 1° C./min to 50° C./min.

The temperature of the heat treatment in the modification step of the second heat treatment step may be from 200° C. to 320° C., preferably 230° C. or higher, or 290° C. or lower. The duration of the heat treatment in the modification step may be, for example, 3 seconds or longer, preferably 1 minute or longer, 10 minutes or longer, 30 minutes or longer, 60 minutes or longer, or 90 minutes or longer. Further, the duration of the heat treatment may be, for example, 300 minutes or shorter, preferably 180 minutes or shorter, or 150 minutes or shorter. The duration of the heat treatment in the modification step is defined that it starts at the time when the temperature reaches a temperature set in the above-described range (e.g., at the time when the temperature reaches 250° C. in a case where the set temperature is 250° C.), and ends at the time when an operation for lowering the temperature is carried out.

The atmosphere of the second heat treatment is preferably an inert gas atmosphere, particularly an argon atmosphere or a nitrogen atmosphere. By using an inert gas atmosphere, the generation of an oxide as a by-product as well as the oxidation of the surfaces of the resulting second semiconductor nanoparticles may be reduced or prevented.

The method of producing semiconductor nanoparticles may include, after the above-described modification step, the cooling step of lowering the temperature of a dispersion containing the resulting second semiconductor nanoparticles. The cooling step starts at the time when an operation for lowering the temperature is carried out, and ends at the time when the dispersion is cooled to 50° C. or lower.

The cooling step may include a period in which the temperature lowering rate is 50° C./min or higher. The temperature lowering rate may be 50° C./min or higher particularly at the time when the temperature starts to decrease after the operation for lowering the temperature is carried out.

The atmosphere of the cooling step is preferably an inert gas atmosphere, particularly an argon atmosphere or a nitrogen atmosphere. By using an inert gas atmosphere, the generation of an oxide as a by-product as well as the oxidation of the surfaces of the resulting second semiconductor nanoparticles may be reduced or prevented.

The method of producing semiconductor nanoparticles may also include a separation step of separating the second semiconductor nanoparticles from the dispersion, and may further include a purification step as required. The separation step and the purification step are as described above in relation to the first semiconductor nanoparticles; therefore, detailed description thereof is omitted here.

The method of producing semiconductor nanoparticles may further include a surface modification step. The surface modification step may include bringing the thus obtained second semiconductor nanoparticles into contact with a surface modifier.

In the surface modification step, the second semiconductor nanoparticles may be brought into contact with the surface modifier by, for example, mixing the second semiconductor nanoparticles and the surface modifier. In the surface modification step, a ratio of the amount of the surface modifier with respect to the second semiconductor nanoparticles may be, for example, 1× 10⁻⁸ moles or more, and it is preferably 2×10⁻⁸ moles or more, or 5×10⁻⁸ moles or less, with respect to 1×10⁻⁸ moles of the second semiconductor nanoparticles. The temperature of the contact may be, for example, from 0° C. to 300° C., and it is preferably 10° C. or higher, or 300° C. or lower. The duration of the contact may be, for example, from 10 seconds to 10 days, and it is preferably 1 minute or longer, or 1 day or shorter. The atmosphere of the contact may be an inert gas atmosphere, and it is particularly preferably an argon atmosphere or a nitrogen atmosphere.

Specific examples of the surface modifier used in the surface modification step include an amino alcohol having from 2 to 20 carbon atoms, an ionic surface modifier, a nonionic surface modifier, a nitrogen-containing compound containing a hydrocarbon group having from 4 to 20 carbon atoms, a sulfur-containing compound containing a hydrocarbon group having from 4 to 20 carbon atoms, an oxygen-containing compound containing a hydrocarbon group having from 4 to 20 carbon atoms, a phosphorus-containing compound containing a hydrocarbon group having from 4 to 20 carbon atoms, and a halide containing at least one selected from the group consisting of a Group 2 element, a Group 12 element, and a Group 13 element. These surface modifiers may be used singly, or in combination of two or more different kinds thereof.

The amino alcohol used as the surface modifier may be any compound as long as it has an amino group and an alcoholic hydroxy group and contains a hydrocarbon group having from 2 to 20 carbon atoms. The number of carbon atoms in the amino alcohol is preferably 10 or less, more preferably 6 or less. The hydrocarbon group constituting the amino alcohol may be derived from a hydrocarbon such as a linear, branched, or cyclic alkane, alkene, or alkyne. The expression “derived from a hydrocarbon” used herein means that the hydrocarbon group is formed by removing at least two hydrogen atoms from the hydrocarbon. Specific examples of the amino alcohol include amino ethanol, amino propanol, amino butanol, amino pentanol, amino hexanol, and amino octanol. The amino group of the amino alcohol binds to the surfaces of semiconductor nanoparticles and the hydroxyl group is exposed on the particle outermost surface on the opposite side, as a result of which the polarity of the semiconductor nanoparticles is changed, and the dispersibility in alcohol-based solvents (e.g., methanol, ethanol, propanol, and butanol) is improved.

Examples of the ionic surface modifier used as the surface modifier include nitrogen-containing compounds, sulfur-containing compounds, and oxygen-containing compounds, which contain an ionic functional group in the respective molecules. The ionic functional group may be either cationic or anionic, and the ionic surface modifier preferably contains at least a cationic group. With regard to specific examples of the surface modifier and a surface modification method, reference may be made to, for example, Chemistry Letters, Vol. 45, pp 898-900, 2016.

The ionic surface modifier may be, for example, a sulfur-containing compound containing a tertiary or quaternary alkylamino group. The number of carbon atoms of the alkyl group in the alkylamino group may be, for example, from 1 to 4. The sulfur-containing compound may also be an alkyl or alkenylthiol having from 2 to 20 carbon atoms. Specific examples of the ionic surface modifier include hydrogen halides of dimethylaminoethanethiol, halogen salts of trimethylammonium ethanethiol, hydrogen halides of dimethylaminobutanethiol, and halogen salts of trimethylammonium butanethiol.

Examples of the nonionic surface modifier used as the surface modifier include nitrogen-containing compounds, sulfur-containing compounds, and oxygen-containing compounds, which have a nonionic functional group containing an alkylene glycol unit, an alkylene glycol monoalkyl ether unit, or the like. The number of carbon atoms of the alkylene group in the alkylene glycol unit may be, for example, from 2 to 8, and it is preferably 2 or more, or 4 or less. Further, the number of repeating alkylene glycol units may be, for example, from 1 to 20, and it is preferably 2 or more, or 10 or less. The nitrogen-containing compounds, the sulfur-containing compounds, and the oxygen-containing compounds, which constitute the nonionic surface modifier, may contain an amino group, a thiol group, and a hydroxy group, respectively. Specific examples of the nonionic surface modifier include methoxytriethyleneoxy ethanethiol and methoxyhexaethyleneoxy ethanethiol.

Examples of the nitrogen-containing compound containing a hydrocarbon group having from 4 to 20 carbon atoms include amines and amides. Examples of the sulfur-containing compound containing a hydrocarbon group having from 4 to 20 carbon atoms include thiols. Examples of the oxygen-containing compound containing a hydrocarbon group having from 4 to 20 carbon atoms include carboxylic acids, alcohols, ethers, aldehydes, and ketones. Examples of the phosphorus-containing compound containing a hydrocarbon group having from 4 to 20 carbon atoms include trialkyl phosphines, triaryl phosphines, trialkyl phosphine oxides, and triaryl phosphine oxides.

Examples of the halide containing at least one selected from the group of a Group 2 elements, a Group 12 elements, and a Group 13 element include magnesium chloride, calcium chloride, zinc chloride, cadmium chloride, aluminum chloride, and gallium chloride.

### Semiconductor Nanoparticles

The semiconductor nanoparticles contain a first semiconductor containing copper (Cu), silver (Ag), indium (In), gallium (Ga), and sulfur (S), and a second semiconductor containing Ga and S may be arranged in the surfaces of the semiconductor nanoparticles. The second semiconductor does not have to substantially contain Ag. The semiconductor nanoparticles exhibit band-edge emission with a peak emission wavelength in a wavelength range of 600 nm to 680 nm when irradiated with a light having a wavelength of 365 nm. The band-edge emission purity may be 60% or higher, and the internal quantum yield of the band-edge emission may be 15% or more.

The semiconductor nanoparticles, when irradiated with a light having a wavelength of 365 nm, may exhibit band-edge emission with a peak emission wavelength in a wavelength range of from 600 nm to 680 nm (e.g., red region). In addition, the semiconductor nanoparticles may exhibit a high band-edge emission purity and a high internal quantum yield of the band-edge emission. This is believed to be because, for example, the crystal structure of the first semiconductor existing in the central parts of the semiconductor nanoparticles is substantially tetragonal (chalcopyrite structure), and the second semiconductor arranged in the surfaces of the semiconductor nanoparticles has a crystal structure with few Ga defects (e.g., Ga-deficient parts). The second semiconductor may be a semiconductor having a higher Ga composition ratio than the first semiconductor, a semiconductor having a lower Ag composition ratio than the first semiconductor, or a semiconductor composed of substantially Ga and S. Further, in the semiconductor nanoparticles, a deposit containing the second semiconductor may be arranged on the surfaces of particles containing the first semiconductor, and the particles containing the first semiconductor may be covered with the deposit containing the second semiconductor. Moreover, the semiconductor nanoparticles may have a core-shell structure in which, for example, a particle containing the first semiconductor constitutes a core, and the deposit containing the second semiconductor is arranged as a shell on the surface of the core.

The first semiconductor constituting the semiconductor nanoparticles contains Cu, Ag, In, Ga, and S. Generally, a semiconductor that contains Ag, In, and S, and has a tetragonal, hexagonal, or orthorhombic crystal structure is introduced in literature and the like as a semiconductor represented by a composition formula AgInS₂. The first semiconductor may have a composition represented by (Ag,Cu)(In,Ga)S₂, which is the above-described composition formula in which Ag is partially substituted with Cu and In is partially substituted with Ga. However, such a semiconductor does not actually have a stoichiometric composition represented by the above-described composition formula and, particularly, a ratio (Ag+Cu/In+Ga) of the number of In and Ga atoms with respect to the number of Ag and Cu atoms may be lower than 1, or conversely, higher than 1. In addition, a sum of the number of Ag and Cu atoms and the number of In and Ga atoms is not always equal to the number of S atoms. Therefore, in the present specification, where it is irrelevant whether or not a semiconductor containing specific elements has a stoichiometric composition, the composition of the semiconductor may be represented by a formula in which the constituent elements are connected by “—” as in Cu—Ag—In—Ga—S. Accordingly, the composition of the first semiconductor of the present embodiment can be regard as, for example, Cu—Ag—In—Ga—S or Cu—Ag—Ga—S, which is a composition of Ag—In—S in which Ag that is a Group 11 element is partially substituted with Cu that is also a Group 11 element, and In that is a Group 13 element is partially or entirely substituted with Ga that is also a Group 13 element.

It is noted here that the first semiconductor containing the above-described elements and having a hexagonal crystal structure is a wurtzite-type semiconductor, and the semiconductor having a tetragonal crystal structure is a chalcopyrite-type semiconductor. The crystal structure is identified by, for example, measuring the X-ray diffraction (XRD) pattern obtained by XRD analysis. Specifically, an XRD pattern obtained from the first semiconductor nanoparticles is compared with known XRD patterns of semiconductor nanoparticles represented by a composition formula AgInS₂, or with XRD patterns determined by simulation using crystal structure parameters. If the pattern of the first semiconductor nanoparticles corresponds to any of the known patterns and simulated patterns, the crystal structure of the semiconductor nanoparticles is said to be that of the corresponding known or simulated pattern.

An aggregate of the semiconductor nanoparticles may contain a mixture of semiconductor nanoparticles that contain first semiconductors having different crystal structures. In this case, peaks derived from the plural kinds of crystal structures are observed in the XRD pattern. In the semiconductor nanoparticles of an embodiment, the first semiconductor may be composed of substantially tetragonal crystals, and a peak corresponding to the tetragonal crystals is observed, while substantially no peak derived from other crystal structure may be observed.

In the composition of the first semiconductor, a total content ratio of Ag and Cu may be, for example, from 10% by mole to 30% by mole, and it is preferably 15% by mole or higher, or 25% by mole or lower. In the composition of the first semiconductor, a total content ratio of In and Ga may be, for example, from 15% by mole to 35% by mole, and it is preferably 20% by mole or higher, or 30% by mole or lower. In the composition of the first semiconductor, a total content ratio of S may be, for example, from 35% by mole to 55% by mole, and it is preferably 40% by mole or higher, or 55% by mole or lower.

The first semiconductor may contain at least Ag and Cu, may further contain at least one of Au or an alkali metal, with a portion thereof being substituted, and may be composed of substantially Ag and Cu. The term “substantially” used herein indicates that a ratio of the total number of atoms of Au and the alkali metals is, for example, 10% or lower, preferably 5% or lower, more preferably 1% or lower, with respect to a total number of atoms of Ag, Cu, Au and the alkali metal.

In the composition of the first semiconductor, it may be considered that Ag is partially substituted with Cu. As compare to a case of Ag by itself, partial substitution of Ag with Cu leads to, for example, a narrower band gap with a shift of the peak emission wavelength to the longer wavelength side. In the composition of the first semiconductor, for example, a ratio (Cu/(Cu+Ag)) of the number of moles of Cu with respect to a total number of moles of Cu and Ag may be 0.01 or higher but lower than 1.0, preferably 0.03 or higher, or 0.99 or lower, more preferably 0.05 or higher, or 0.5 or lower. Further, in the composition of the first semiconductor, for example, a ratio ((Cu+Ag)/(Cu+Ag+In+Ga)) of a total number of moles of Cu and Ag with respect to a total number of moles of Cu, Ag, In, and Ga may be 0.1 or higher and lower than 1.0, preferably 0.2 or higher, or 0.99 or lower.

Further, The first semiconductor may substantially contain Ag, Cu, and an alkali metal (hereinafter, may be simply referred to as “M^{a}”) as constituent elements. The term “substantially” used herein indicates that a ratio of the total number of atoms of elements other than Ag, Cu and the alkali metal is, for example, 10% or lower, preferably 5% or lower, more preferably 1% or lower, with respect to a total number of atoms of Ag, Cu, the alkali metal, and the elements other than Ag, Cu and the alkali metal. Examples of the alkali metal include lithium (Li), sodium (Na), potassium (K), rubidium (Rb), and cesium (Cs). The alkali metal may be a monovalent cation in the same manner as Ag and, therefore, may partially substitute Ag in the composition of the semiconductor nanoparticles. Particularly, Li is preferably used because it has substantially the same ionic radius as Ag. Partial substitution of Ag in the composition of the first semiconductor leads to, for example, a widened band gap and a shift of the peak emission wavelength to the shorter wavelength side. In addition, it is believed that, although the details are unclear, the lattice defects of the first semiconductor are reduced and the internal quantum yield of the band-edge emission is improved. When the first semiconductor contains an alkali metal, the first semiconductor may contain at least Li.

When the first semiconductor contains Ag, Cu, and an alkali metal (M^{a}), a content ratio of the alkali metal in the composition of the first semiconductor is, for example, higher than 0% by mole and lower than 30% by mole, preferably 1% by mole or higher, or 25% by mole or lower. Further, in the composition of the first semiconductor, a ratio (M^{a}/(Ag+Cu+M^{a})) of the number of alkali metal (M^{a}) atoms with respect to a total of the number of Ag atoms, the number of Cu atoms and the number of alkali metal (M^{a}) atoms is, for example, lower than 1, preferably 0.8 or lower, more preferably 0.4 or lower, still more preferably 0.2 or lower. This ratio is, for example, higher than 0, preferably 0.05 or higher, more preferably 0.1 or higher.

The first semiconductor may contain at least In and Ga, may further contain at least one of Al or Tl, with a portion thereof being substituted, and may be composed of substantially In and Ga. The term “substantially” used herein indicates that a ratio of the total number of atoms of Al and Tl is, for example, 10% or lower, preferably 5% or lower, more preferably 18 or lower, with respect to a total number of atoms of In, Ga, Al and Tl.

In the first semiconductor, a ratio (In/(In+Ga)) of the number of In atoms with respect to a total number of In and Ga atoms may be, for example, 0.01 or higher but lower than 1, preferably 0.1 or higher, or 0.99 or lower. When the ratio of the number of In atoms with respect to a total number of In and Ga atoms is in this prescribed range, a short peak emission wavelength (e.g., 545 nm or shorter) can be obtained. Further, a ratio (Ag/(In+Ga)) of the number of Ag atoms with respect to a total number of In and Ga atoms may be, for example, from 0.1 to 1.2, preferably 0.2 or higher, or 1.1 or lower. Moreover, a ratio ((Ag+Cu)/(In+Ga)) of a total number of Ag and Cu atoms with respect to a total number of In and Ga atoms may be, for example, from 0.1 to 1.2, preferably 0.2 or higher, or 1.0 or lower. A ratio (S/(Ag+In+Ga)) of the number of S atoms with respect to a total number of atoms of Ag, In, and Ga may be, for example, from 0.8 to 1.5, preferably 0.9 or higher, or 1.2 or lower. A ratio (S/(Ag+Cu+In+Ga)) of the number of S atoms with respect to a total number of atoms of Ag, Cu, In, and Ga may be, for example, from 0.8 to 1.5, preferably 0.9 or higher, or 1.2 or lower.

The first semiconductor may contain S, may further contain at least one of Se or Te, with a portion thereof being substituted, and may be composed of substantially S. The term “substantially” used herein indicates that a ratio of the total number of atoms of Se and Te is, for example, 10% or lower, preferably 5% or lower, more preferably 1% or lower, with respect to a total number of atoms of S, Se, and Te.

The first semiconductor may be composed of substantially Cu, Ag, In, Ga, S, and the above-described elements partially substituting these elements. The term “substantially” used herein takes into consideration that elements other than Cu, Ag, In, Ga, S, and the elements partially substituting these elements may be unavoidably incorporated due to, for example, contamination with impurities.

The first semiconductor may have a composition represented by, for example, the following formula (1):

(AgₚCu₍₁₋ₚ₎)_{q}InᵣGa₍₁₋ᵣ₎S_{(q+3)/2} (1),
wherein, p, q, and r satisfy 0<p<1, 0.20<q≤1.2, and 0<r<1.

A second semiconductor may be arranged in the surfaces of the semiconductor nanoparticles. The second semiconductor may contain a semiconductor having a larger band-gap energy than that of the first semiconductor. The composition of the second semiconductor may have a higher Ga molar content than the composition of the first semiconductor. A ratio of the Ga molar content in the composition of the second semiconductor with respect to the Ga molar content in the composition of the first semiconductor may be, for example, higher than 1 but 5 or lower, preferably 1.1 or higher but 3 or lower.

Further, the composition of the second semiconductor may have a lower molar content of Ag than the composition of the first semiconductor. A ratio of the molar content of Ag in the composition of the second semiconductor with respect to the molar content of Ag in the composition of the first semiconductor may be, for example, from 0.1 to 0.7, preferably 0.2 or higher, and preferably 0.5 or lower. The ratio of the molar content of Ag in the composition of the second semiconductor may be, for example, 0.5 or lower, preferably 0.2 or lower, 0.1 or lower, or substantially 0. The term “substantially” used herein indicates that, when a total number of atoms of all elements contained in the second semiconductor is taken as 100%, a ratio of the number of Ag is, for example, 10% or lower, preferably 5% or lower, more preferably 1% or lower.

The second semiconductor arranged in the surfaces of the semiconductor nanoparticles may contain a semiconductor containing Ga and S. This semiconductor containing Ga and S may be a semiconductor having a larger band-gap energy than that of the first semiconductor.

In the composition of the semiconductor containing Ga and S that is contained in the second semiconductor, Ga may be partially substituted with at least one Group 13 element selected from the group consisting of boron (B), aluminum (Al), indium (In), and thallium (Tl). Further, S may be partially substituted with at least one Group 16 element selected from the group consisting of oxygen (O), selenium (Se), tellurium (Te), and polonium (Po).

The semiconductor containing Ga and S may be a semiconductor composed of substantially Ga and S. The term “substantially” used herein indicates that, when a total number of atoms of all elements contained in the semiconductor containing Ga and S is taken as 100%, a ratio of the number of atoms of elements other than Ga and S is, for example, 10% or lower, preferably 5% or lower, more preferably 1% or lower.

The semiconductor containing Ga and S may be formed by selecting its composition and the like in accordance with the band-gap energy of the above-described first semiconductor. Alternatively, when the composition and the like of the semiconductor containing Ga and S are predetermined, the first semiconductor may be designed such that the band-gap energy of the first semiconductor is smaller than that of the semiconductor containing Ga and S. Generally, a semiconductor composed of Ag—In—S has a band-gap energy of 1.8 eV to 1.9 eV.

Specifically, the semiconductor containing Ga and S may have a band-gap energy of, for example, 2.0 eV to 5.0 eV, particularly 2.5 eV to 5.0 eV. The band-gap energy of the semiconductor containing Ga and S may be larger than that of the first semiconductor by, for example, about 0.1 eV to 3.0 eV, particularly about 0.3 eV to 3.0 eV, more particularly about 0.5 eV to 1.0 eV. When the difference between the band-gap energy of the semiconductor containing Ga and S and that of the first semiconductor is equal to or greater than the above-described lower limit value, the ratio of emission other than band-edge emission in the emission from the semiconductor nanoparticles tends to be reduced, resulting in an increase in the ratio of band-edge emission.

The second semiconductor may contain an oxygen (O) atom. An oxygen atom-containing semiconductor tends to have a larger band-gap energy than the above-described first semiconductor. The form of an oxygen atom-containing semiconductor in the second semiconductor is not clear; however, it may be, for example, Ga—O—S or Ga₂O₃.

The second semiconductor may further contain an alkali metal (M^{a}) in addition to Ga and S. The alkali metal contained in the second semiconductor may include at least lithium. When the second semiconductor contains an alkali metal, a ratio of the number of alkali metal atoms with respect to a sum of the number of alkali metal atoms and the number of Ga atoms may be, for example, 0.01 or higher and lower than 1, preferably 0.1 or higher, or 0.9 or lower. Further, a ratio of the number of S atoms with respect to a sum of the number of alkali metal atoms and the number of Ga atoms may be, for example, from 0.25 to 0.75.

The second semiconductor may have a crystal system conforming to that of the first semiconductor, and may have a lattice constant that is the same as or close to that of the first semiconductor. The second semiconductor which has a crystal system conforming to that of the first semiconductor and a lattice constant close to that of the first semiconductor (including a case where a multiple of the lattice constant of the second semiconductor is similar to the lattice constant of the semiconductor contained in the first semiconductor) may favorably cover the periphery of the first semiconductor. For example, the semiconductor contained in the first semiconductor generally has a tetragonal crystal system, and examples of a crystal system conforming thereto include a tetragonal crystal system and an orthorhombic crystal system. When Ag—In—S has a tetragonal crystal system, it is preferred that the lattice constants of its constituent elements be 0.5828 nm, 0.5828 nm, and 1.119 nm, respectively; and that the second semiconductor covering this Ag—In—S have a tetragonal or cubic crystal system, and its lattice constants or multiple thereof be close to the lattice constants of Ag—In—S. Alternatively, the second semiconductor may be amorphous.

Whether or not an amorphous second semiconductor is formed may be verified by observing the semiconductor nanoparticles by HAADF-STEM. When the amorphous second semiconductor is formed, specifically, in HAADF-STEM, a central part is observed with a regular pattern, such as a stripe pattern or a dot pattern, and its surrounding part is observed with no regular pattern. According to HAADF-STEM, a substance having a regular structure as in the case of a crystalline substance is observed as an image having a regular pattern, while a substance having no regular structure as in the case of an amorphous substance is not observed as an image having a regular pattern. Therefore, when the second semiconductor is amorphous, the second semiconductor may be observed as a part that is clearly different from the first semiconductor observed as an image having a regular pattern (the first semiconductor may have a crystal structure of a tetragonal system or the like).

When the second semiconductor is formed of Ga—S, because Ga is an element lighter than Ag and In that are contained in the first semiconductor, the second semiconductor tends to be observed darker than the first semiconductor in an image obtained by HAADF-STEM.

Whether or not an amorphous second semiconductor is formed may also be verified by observing the semiconductor nanoparticles of the present embodiment under a high-resolution transmission electron microscope (HRTEM). In an image obtained by HRTEM, the first semiconductor portion is observed as a crystal lattice image (an image having a regular pattern) while the second semiconductor portion being amorphous is not observed as a crystal lattice image, and the second semiconductor portion is observed as a part having a black and white contrast but no regular pattern.

Meanwhile, the second semiconductor preferably does not form a solid solution with the first semiconductor. If the second semiconductor forms a solid solution with the first semiconductor, because the second semiconductor and the first semiconductor are integrated together, the mechanism of the present embodiment, in which band-edge emission is obtained by covering the first semiconductor with the second semiconductor and thereby modifying the surface state of the first semiconductor, cannot be attained. For example, it has been confirmed that band-edge emission cannot be obtained from the first semiconductor even when the surface of the first semiconductor composed of Ag—In—S is covered with zinc sulfide (Zn—S) having a stoichiometric or non-stoichiometric composition. Zn—S, in its relationship with Ag—In—S, satisfies the above-described conditions in terms of band-gap energy, and gives a type-I band alignment. Nevertheless, band-edge emission was not obtained from the above-described specific semiconductor, and it is surmised that the reason for this is because the semiconductor of the first semiconductor and ZnS formed a solid solution.

The semiconductor nanoparticles may have an average particle size of, for example, 50 nm or smaller. From the viewpoints of the ease of production and the internal quantum yield of band-edge emission, the average particle size is preferably in a range of from 1 nm to 20 nm, more preferably 1.6 nm or larger, or 8 nm or smaller, particularly preferably 2 nm or larger, or 7.5 nm or smaller.

The average particle size of the semiconductor nanoparticles may be determined from, for example, a TEM image captured using a transmission electron microscope (TEM). The particle size of an individual particle specifically refers to the length of the longest line segment among those line segments that exist inside the particle observed in a TEM image and connect two arbitrary points on the circumference of the particle.

However, for a rod-shaped particle, the length of its short axis is regarded as the particle size. The term “rod-shaped particle” used herein refers to a particle observed in a TEM image to have a short axis and a long axis perpendicular to the short axis, in which a ratio of the length of the long axis with respect to the length of the short axis is higher than 1.2. In a TEM image, a rod-shaped particle is observed to have, for example, a quadrangular shape such as a rectangular shape, an elliptical shape, or a polygonal shape. The shape of a cross-section that is a plane perpendicular to the long axis of the rod shape may be, for example, circular, elliptical, or polygonal. Specifically, for a rod-shaped particle having an elliptical shape, the length of the long axis means the length of the longest line segment among those line segments connecting any two points on the circumference of the particle and, for a rod-shaped particle having a rectangular or polygonal shape, the length of the long axis means the length of the longest line segment among those line segments that are parallel to the longest side among all sides defining the circumference of the particle and connect any two points on the circumference of the particle. The length of the short axis means the length of the longest line segment that is perpendicular to the line segment defining the length of the long axis, among those line segments connecting any two points on the circumference of the particle.

The average particle size of the semiconductor nanoparticles is determined by measuring the particle size for all measurable particles observed in a TEM image captured at a magnification of from ×50,000 to ×150,000, and calculating the arithmetic mean of the thus measured values. The “measurable” particles are those particles whose outlines are entirely observable in a TEM image. Accordingly, in a TEM image, a particle whose outline is partially not included in the captured area and thus a part of which particle appears to be “cut off” is not a measurable particle. When a single TEM image contains 100 or more measurable particles, the average particle size is determined using this TEM image. Meanwhile, when a single TEM image contains less than 100 measurable particles, another TEM image is captured at a different position, and the particle size is measured for 100 or more measurable particles contained in two or more TEM images to determine the average particle size.

In the semiconductor nanoparticles, the parts composed of the first semiconductor may be in a particulate form and have an average particle size of, for example, 10 nm or smaller, particularly 8 nm or smaller, or smaller than 7.5 nm. The average particle size of the first semiconductor may be in a range of from 1.5 nm to 10 nm, preferably in a range of 1.5 nm or larger and smaller than 8 nm, or 1.5 nm or larger and smaller than 7.5 nm. When the average particle size of the first semiconductor is equal to or smaller than the above-described upper limit value, a quantum size effect is likely to be obtained.

In the semiconductor nanoparticles, the parts composed of the second semiconductor may have a thickness in a range of from 0.1 nm to 50 nm, or from 0.1 nm to 10 nm, particularly in a range of from 0.3 nm to 3 nm. When the thickness of the second semiconductor is equal to or larger than the above-described lower limit value, the effect provided by covering the first semiconductor with the second semiconductor is sufficiently exerted, so that band-edge emission is likely to be obtained.

The average particle size of the first semiconductor and the thickness of the second semiconductor may be determined by, for example, observing the semiconductor nanoparticles by HAADF-STEM. Particularly, when the second semiconductor is amorphous, the thickness of the second semiconductor easily observable by HAADF-STEM as a part different from the first semiconductor may be easily determined. In this case, the particle size of the first semiconductor may be determined in accordance with the method described above for semiconductor nanoparticles. When the thickness of the second semiconductor is not uniform, the smallest thickness is defined as the thickness of the second semiconductor in the particles of interest.

The semiconductor nanoparticles preferably have a substantially tetragonal crystal structure. The crystal structure is identified by, for example, measuring the X-ray diffraction (XRD) pattern obtained by XRD analysis in the same manner as described above. The term “substantially tetragonal crystal” used herein indicates that a ratio of the height of a peak at about 48°, which represents hexagonal and orthorhombic crystals, with respect to a main peak at about 26°, which represents a tetragonal crystal, is, for example, 10% or less, or 5% or less.

The semiconductor nanoparticles, when irradiated with a light having a wavelength of 365 nm, may exhibit band-edge emission having a peak emission wavelength in a wavelength range of from 600 nm to 680 nm and the range of the peak emission wavelength may be preferably 610 nm or longer, or 670 nm or shorter, more preferably 620 nm or longer, or 660 nm or shorter. In the emission spectrum of the semiconductor nanoparticles, the full width at half maximum may be, for example, 70 nm or less, preferably 65 nm or less, or 60 nm or less. A lower limit of the full width at half maximum may be, for example, 15 nm or more. Further, the emission lifetime of a main component (band-edge emission) is preferably 200 ns or shorter.

The term “emission lifetime” used herein refers to a lifetime of emission that is measured using a device called fluorescence lifetime measuring device. Specifically, the above-descried “emission lifetime of a main component” may be determined by the following procedure. First, the semiconductor nanoparticles are allowed to emit light by irradiation with an excitation light, and a change in the attenuation (afterglow) over time is measured for a light having a wavelength near the spectral emission peak, for example, a wavelength within a range of (peak wavelength±50 nm). The measurement of the change over time is initiated upon termination of the irradiation of the excitation light. The resulting attenuation curve is generally a sum of plural attenuation curves derived from relaxation processes of emission, heat, and the like. Accordingly, in the present embodiment, assuming that the attenuation curve contains three components (i.e. three attenuation curves), parameter fitting is performed such that the attenuation curve is represented by the following formula where I(t) denotes the emission intensity. The parameter fitting is performed using a special software.

$$I ( t ) = {A}_{1} exp ( - t / {τ}_{1} ) + {A}_{2} exp ( - t / {τ}_{2} ) + {A}_{3} exp ( - t / {τ}_{3} )$$

In the above formula, τ₁, τ₂, and τ₃ of the respective components each denote the time required for attenuation of the emission intensity to an initial value of 1/e (36.8%), which corresponds to the emission lifetime of each component. The emission lifetime is in ascending order of τ₁, τ₂, and τ₃. Further, A₁, A₂, and A₃ denote contribution ratios of the respective components. For example, when a component having the largest integral value of curves represented by Aₓ exp(−t/τₓ) is defined as the main component, the main component has an emission lifetime τ of 200 ns or shorter. Such emission is presumed to be band-edge emission. For identification of the main component, the values of Aₓ×τₓ obtained by integration of the t value of Aₓ exp(−t/τₓ) from 0 to infinity are compared, and a component having the largest value is defined as the main component.

It is noted here that an actual attenuation curve is not much different from those attenuation curves that are each drawn from a formula obtained by performing parameter fitting where the emission attenuation curve is assumed to contain three, four, or five components. Therefore, for determination of the emission lifetime of the main component in the present embodiment, the number of components contained in the emission attenuation curve is assumed to be three so as to avoid complicated parameter fitting.

The emission of the semiconductor nanoparticles may include defect emission (e.g., donor-acceptor emission) in addition to band-edge emission; however, the emission is preferably substantially band-edge emission alone. Defect emission generally has a longer emission lifetime and a broader spectrum with a peak on the longer wavelength side as compared to band-edge emission. The expression “substantially band-edge emission alone” used herein means that the purity of the band-edge emission component in the emission spectrum (hereinafter, also referred to as “band-edge emission purity”) is 40% or higher, and this purity is preferably 70% or higher, more preferably 80% or higher, still more preferably 90% or higher, particularly preferably 95% or higher. An upper limit value of the purity of the band-edge emission component may be, for example, 100% or lower, lower than 100%, or 99% or lower. The “purity of the band-edge emission component” is represented by the following formula when parameter fitting, where a band-edge emission peak and a defect emission peak are assumed to each have a shape of normal distribution, is performed for the emission spectrum to separate its peaks into two types, which are the band-edge emission peak and the defect emission peak, and the areas of these peaks are denoted as a₁ and a₂, respectively:

$$Purity ( \% ) of band - edge emission component = {a}_{1} / ( {a}_{1} + {a}_{2} ) \times 100.$$

When the emission spectrum contains no band-edge emission at all, i.e. when the emission spectrum contains only defect emission, the purity of the band-edge emission component is 0%; when the emission spectrum contains band-edge emission and defect emission that have the same peak area, the purity of the band-edge emission component is 50%; and when the emission spectrum contains only band-edge emission, the purity of the band-edge emission component is 100%.

The internal quantum yield of the band-edge emission is defined as a value obtained by multiplying the internal quantum yield, which is measured using a quantum yield measuring device at a temperature of 25° C. and calculated under the conditions of an excitation light wavelength of 450 nm and a fluorescence wavelength range of from 470 nm to 900 nm, an excitation light wavelength of 365 nm and a fluorescence wavelength range of from 450 nm to 950 nm, or an excitation light wavelength of from 450 nm and a fluorescence wavelength range of from 500 nm to 950 nm, by the above-described purity of the band-edge emission component, and dividing the product by 100. The quantum yield of the band-edge emission of the semiconductor nanoparticles is, for example, 15% or more, preferably 50% or more, more preferably 60% or more, still more preferably 70% or more, particularly preferably 80% or more.

The peak position of the band-edge emission by the semiconductor nanoparticles may be shifted by modifying the particle size of the semiconductor nanoparticles. For example, when the particle size of the semiconductor nanoparticles is reduced, the peak wavelength of the band-edge emission tends to shift to the shorter wavelength side. A further reduction in the particle size of the semiconductor nanoparticles tends to further reduce the spectral full width at half maximum of the band-edge emission.

When the semiconductor nanoparticles exhibit defect emission in addition to band-edge emission, the intensity ratio of the band-edge emission may be, for example, 0.75 or higher, and it is preferably 0.85 or higher, more preferably 0.9 or higher, particularly preferably 0.93 or higher. An upper limit value thereof may be, for example, 1 or lower, lower than 1, or 0.99 or lower. The intensity ratio of the band-edge emission is represented by the following formula when parameter fitting, where a band-edge emission peak and a defect emission peak are assumed to each have a shape of normal distribution, is performed for the emission spectrum to separate its peaks into two types, which are the band-edge emission peak and the defect emission peak, and the maximum intensities of these peaks are denoted as b₁ and b₂, respectively:

Intensity ratio of band-edge emission=b₁/(b₁+b₂).

When the emission spectrum contains no band-edge emission at all, i.e. when the emission spectrum contains only defect emission, the intensity ratio of the band-edge emission is 0; when the emission spectrum contains band-edge emission and defect emission that have the same maximum peak intensity, the intensity ratio of the band-edge emission is 0.5; and when the emission spectrum contains only band-edge emission, the intensity ratio of the band-edge emission is 1.

The semiconductor nanoparticles preferably also exhibit an absorption or excitation spectrum (also referred to as “fluorescence excitation spectrum”) with an exciton peak. An exciton peak is a peak resulting from exciton formation, and the appearance of this peak in an absorption or excitation spectrum means that the particles have a small particle size distribution and few crystal defects, and are thus suitable for band-edge emission. A sharper exciton peak means that an aggregate of the semiconductor nanoparticles contains a greater amount of particles having a uniform particle size with few crystal defects. Accordingly, it is expected that the semiconductor nanoparticles exhibit emission with a narrower full width at half maximum and an improved emission efficiency. In the absorption or excitation spectrum of the semiconductor nanoparticles of the present embodiment, an exciton peak is observed, for example, in a range of from 400 nm to 550 nm, preferably from 430 nm to 500 nm. The excitation spectrum for checking the presence or absence of an exciton peak may be measured by setting the observation wavelength around the peak wavelength.

The surfaces of the semiconductor nanoparticles may be modified with a surface modifier. Specific examples of the surface modifier include an amino alcohol having from 2 to 20 carbon atoms, an ionic surface modifier, a nonionic surface modifier, a nitrogen-containing compound containing a hydrocarbon group having from 4 to 20 carbon atoms, a sulfur-containing compound containing a hydrocarbon group having from 4 to 20 carbon atoms, an oxygen-containing compound containing a hydrocarbon group having from 4 to 20 carbon atoms, a phosphorus-containing compound containing a hydrocarbon group having from 4 to 20 carbon atoms, and a halide of a Group 2, 12, or 13 element. These surface modifiers may be used singly, or in combination of two or more different kinds thereof. The details of the above-exemplified surface modifiers are as described above.

The surfaces of the semiconductor nanoparticles may also be modified with gallium halide. By modifying the surfaces of the semiconductor nanoparticles with gallium halide, the internal quantum yield of the band-edge emission is improved. Specific examples of the gallium halide in the second mixture include gallium fluoride, gallium chloride, gallium bromide, and gallium iodide.

The second semiconductor in the semiconductor nanoparticles may be surface-modified with gallium halide. By surface-modifying the surface of the second semiconductor in the semiconductor nanoparticle with gallium halide, the internal quantum yield of band edge emission is improved.

The emission of the semiconductor nanoparticles surface-modified with gallium halide may include defect emission (donor-acceptor emission) in addition to band-edge emission; however, the emission is preferably substantially band-edge emission alone. The expression “substantially band-edge emission alone” used herein means that, as described for the above-described semiconductor nanoparticles, the purity of the band-edge emission component is preferably 70% or higher, more preferably 80% or higher, still more preferably 90% or higher, particularly preferably 95% or higher.

The measurement of the internal quantum yield of the band-edge emission of the semiconductor nanoparticles surface-modified with gallium halide is as described for the above-described semiconductor nanoparticles, and the internal quantum yield of the band-edge emission is, for example, 15% or more, preferably 50% or more, more preferably 60% or more, still more preferably 70% or more, particularly preferably 80% or more.

### Light Emitting Device

The light emitting device includes: a light conversion member containing the above-described semiconductor nanoparticles; and a semiconductor light emitting element. According to this light emitting device, for example, the semiconductor nanoparticles absorb a portion of the light irradiated from the semiconductor light emitting element and emit a long-wavelength light. Further, the light emitted from the semiconductor nanoparticles is combined with the remainder of the light irradiated from the semiconductor light emitting element, and the resulting mixed light may be utilized as a light emitted from the light emitting device.

Specifically, by using a semiconductor light emitting element that emits blue-violet light or blue light having a peak wavelength of about from 400 nm to 490 nm as the above-described semiconductor light emitting element and semiconductor nanoparticles that absorb blue light and emit yellow light as the above-described semiconductor nanoparticles, a light emitting device that emits white light may be obtained. A white light emitting device may also be obtained by using, as the above-described semiconductor nanoparticles, two kinds of semiconductor nanoparticles, which are those that absorb blue light and emit green light and those that absorb blue light and emit red light.

Alternatively, a white light emitting device may be obtained even in the case of using a semiconductor light emitting element that emits ultraviolet rays having a peak wavelength of 400 nm or shorter and three kinds of semiconductor nanoparticles that each absorb ultraviolet rays and emit blue light, green light, or red light. In this case, it is desired that all of the light emitted from the light emitting element be absorbed and converted by the semiconductor nanoparticles so that the ultraviolet rays emitted from the light emitting element do not leak to the outside.

Further, a white light emitting device may be obtained by using a semiconductor light emitting element that emits blue-green light having a peak wavelength of about from 490 nm to 510 nm and semiconductor nanoparticles that absorb the blue-green light and emit red light.

Moreover, it is possible to obtain a light emitting device that emits near-infrared rays by using a semiconductor light emitting element that emits visible light, for example, one which emits red light having a wavelength of from 700 nm to 780 nm, as the above-described semiconductor light emitting element, and semiconductor nanoparticles that absorb visible light and emit near-infrared rays as the above-described semiconductor nanoparticles.

The semiconductor nanoparticles may be used in combination with other semiconductor quantum dots, or any other phosphors that are not quantum dots (e.g., organic phosphors or inorganic phosphors). The other semiconductor quantum dots are, for example, binary semiconductor quantum dots. As the phosphors that are not quantum dots, for example, garnet-based phosphors such as aluminum-garnet phosphors may be used. Examples of the garnet-based phosphors include a cerium-activated yttrium-aluminum-garnet phosphor, and a cerium-activated lutetium-aluminum-garnet phosphor. Examples of phosphors that may be used also include: nitrogen-containing calcium aluminosilicate-based phosphors activated by europium and/or chromium; silicate-based phosphors activated by europium; β-SiAlON-based phosphors; nitride-based phosphors, such as CASN-based or SCASN-based phosphors; rare earth nitride-based phosphors, such as LnSi₃N₁₁-based or LnSiAlON-based phosphors; oxynitride-based phosphors, such as BaSi₂O₂N₂:Eu-based or Ba₃Si₆O₁₂N₂:Eu-based phosphors; sulfide-based phosphors, such as CaS-based, SrGa₂S₄-based, or ZnS-based phosphors; chlorosilicate-based phosphors; SrLiAl₃N₄:Eu phosphor; SrMg₃SiN₄:Eu phosphor; and manganese-activated fluoride complex phosphors, such as a K₂SiF₆:Mn phosphor.

In the light emitting device, the light conversion member containing the semiconductor nanoparticles may be, for example, a sheet or a plate-like member, or may be a member having a three-dimensional shape. One example of the member having a three-dimensional shape is, in a surface-mount light-emitting diode in which a semiconductor light emitting element is arranged on the bottom surface of a recess formed in a package, a sealing member that is formed by filling the recess with a resin to seal the light emitting element.

Another example of the light conversion member is, in a case where a semiconductor light emitting element is arranged on a planar substrate, a resin member that is formed in such a manner to surround the upper surface and side surfaces of the semiconductor light emitting element with a substantially uniform thickness. Yet another example of the light conversion member is, in a case where the surrounding of a semiconductor light emitting element is filled with a reflective material-containing resin member such that the upper end of this resin member forms a single plane with the semiconductor light emitting element, a resin member that is formed in a plate-like shape with a prescribed thickness on top of the semiconductor light emitting element and the reflective material-containing resin member.

The light conversion member may be in contact with the semiconductor light emitting element, or may be arranged apart from the semiconductor light emitting element. Specifically, the light conversion member may be a pellet-like, sheet-like, plate-like, or rod-like member arranged apart from the semiconductor light emitting element, or a member arranged in contact with the semiconductor light emitting element, such as a sealing member, a coating member (a member covering the light emitting element that is arranged separately from a molded member), or a molded member (e.g., a lens-shaped member).

In the light emitting device, when two or more kinds of semiconductor nanoparticles that emit different wavelengths of light are used, the two or more kinds of semiconductor nanoparticles may be mixed within a single light conversion member, or two or more light conversion members each containing only a single kind of semiconductor nanoparticles may be used in combination. In the latter case, the two or more light conversion members may form a laminated structure, or may be arranged in a dot-like or striped pattern on a plane.

One example of the semiconductor light emitting element is an LED chip. The LED chip may include a semiconductor layer composed of one or more selected from the group consisting of GaN, GaAs, InGaN, AlInGaP, GaP, SiC, and ZnO. A semiconductor light emitting element that emits blue-violet light, blue light, or ultraviolet rays includes a semiconductor layer composed of, for example, a GaN compound having a composition represented by In_{X}Al_{Y}G_{a1-X-Y}N, wherein, 0≤x, 0≤Y, X+Y<1.

The light emitting device of the present embodiment is preferably incorporated as a light source in a liquid-crystal display device. Because the band-edge emission by the semiconductor nanoparticles has a short emission lifetime, a light emitting device using the semiconductor nanoparticles is suitable as a light source of a liquid-crystal display device that requires a relatively high response speed. Further, the semiconductor nanoparticles of the present embodiment may exhibit band-edge emission having an emission peak with a small full width at half maximum. Therefore, a liquid-crystal display device having good color reproducibility may be obtained without the use of a thick color filter by configuring the light emitting device such that: blue light having a peak wavelength in a range of from 420 nm to 490 nm is provided by a blue semiconductor light emitting element, while green light having a peak wavelength in a range of from 510 nm to 550 nm, preferably from 530 nm to 540 nm, and red light having a peak wavelength in a range of from 600 nm to 680 nm, preferably from 630 nm to 650 nm, are provided by the semiconductor nanoparticles; or ultraviolet light having a peak wavelength of 400 nm or shorter is provided by a semiconductor light emitting element, while blue light having a peak wavelength in a range of from 430 nm to 470 nm, preferably from 440 nm to 460 nm, green light having a peak wavelength in a range of from 510 nm to 550 nm, preferably from 530 nm to 540 nm, and red light having a peak wavelength in a range of from 600 nm to 680 nm, preferably from 630 nm to 650 nm, are provided by the semiconductor nanoparticles. The light emitting device may be used as, for example, a direct backlight or an edge backlight.

Alternatively, a sheet, a plate-like member, or a rod, which contains the semiconductor nanoparticles and is made of a resin or glass, may be incorporated into a liquid-crystal display device as a light conversion member independent of the light emitting device.

The present disclosure may further include the following embodiments.

[1] A method of producing semiconductor nanoparticles, the method comprising performing a first heat treatment of a first mixture, which comprises a copper (Cu) salt, a silver (Ag) salt, a salt comprising at least one of indium (In) or gallium (Ga), a gallium halide, and an organic solvent, to obtain first semiconductor nanoparticles, wherein at least one of the Cu salt, the Ag salt, or the salt comprising at least one of In or Ga in the first mixture comprises a compound having a bond formed of a metal and sulfur (S).

[2] The method of producing semiconductor nanoparticles according to [1], wherein, in the first mixture, a content molar ratio of the gallium halide with respect to a total amount of the Ag salt and the Cu salt is 0.01 to 1.

[3] The method of producing semiconductor nanoparticles according to [1] or [2], wherein a total concentration of the Ag salt and the Cu salt in the first mixture is 0.001 mmol/L to 500 mmol/L.

[4] The method of producing semiconductor nanoparticles according to any one of [1] to [3], wherein the first heat treatment is performed at 200° C. to 320° C.

[5] The method of producing semiconductor nanoparticles according to any one of [1] to [4], wherein the gallium halide in the first mixture comprises gallium chloride.

[6] The method of producing semiconductor nanoparticles according to any one of [1] to [5], wherein the Cu salt in the first mixture comprises a compound having a Cu—S bond.

[7] The method of producing semiconductor nanoparticles according to any one of [1] to [6], the method further comprising performing a second heat treatment of a second mixture, which comprises the first semiconductor nanoparticles and a gallium halide, to obtain second semiconductor nanoparticles.

[8] The method of producing semiconductor nanoparticles according to [7], wherein, in the second mixture, a molar ratio of the gallium halide with respect to the first semiconductor nanoparticles is 0.01 to 50.

[9] The method of producing semiconductor nanoparticles according to [7] or [8], wherein the gallium halide in the second mixture comprises gallium chloride.

[10] The method of producing semiconductor nanoparticles according to any one of [7] to [9], wherein the second heat treatment is performed at 200° C. to 320° C.

[11] Semiconductor nanoparticles comprising a first semiconductor that comprises copper (Cu), silver (Ag), indium (In), gallium (Ga), and sulfur (S), wherein a second semiconductor that comprises Ga and S but does not substantially contain Ag is arranged in the surfaces of the semiconductor nanoparticles, the semiconductor nanoparticles exhibit band-edge emission with a peak emission wavelength in a wavelength range of 600 nm to 680 nm when irradiated with a light having a wavelength of 365 nm, the band-edge emission purity is 60% or higher, and the internal quantum yield of the band-edge emission is 15% or more.

[12] The semiconductor nanoparticles according to [11], wherein an emission spectrum of the semiconductor nanoparticles has a full width at half maximum of 70 nm or less.

[13] The semiconductor nanoparticles according to [11] or [12], wherein the surfaces of the semiconductor nanoparticles are modified with a gallium halide.

[14] A light emitting device, comprising: a light conversion member comprising the semiconductor nanoparticles according to any one of [11] to [13]; and a semiconductor light emitting element.

[15] The light emitting device according to [14], wherein the semiconductor light emitting element is an LED chip.

### EXAMPLES

The present invention will now be described more concretely by way of Examples; however, the present invention is not limited to the below-described Examples.

### Example 1

### First Step

A first mixture was obtained by mixing 0.1 mmol of copper (I) ethylxanthate (Cu(EX)), 0.4 mmol of silver ethylxanthate (Ag(EX)), 0.5 mmol of indium acetate (In(OAc)₃), 1.0 mmol of gallium acetylacetonate (Ga(acac)₃), and 0.075 mmol of gallium chloride (GaCl₃) with 100 mL of oleylamine (OLA). This first mixture was heat-treated at 260° C. for 120 minutes with stirring in a nitrogen atmosphere. The thus obtained suspension was allowed to cool and then centrifuged (radius: 146 mm, at 2,800 rpm for 5 minutes), and the resulting precipitate was removed to obtain a dispersion of first semiconductor nanoparticles.

### Measurement of Emission Spectrum

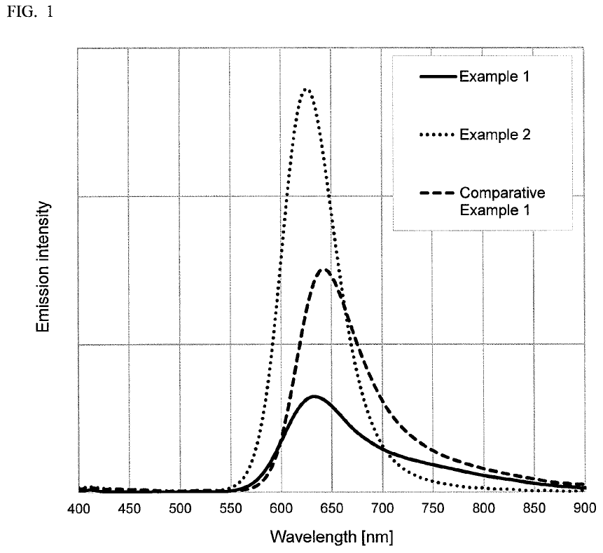

Emission spectrum of the thus obtained first semiconductor nanoparticles was measured, and the peak band-edge emission wavelength, the full width at half maximum, the band-edge emission purity, and the internal quantum yield of band-edge emission were determined. It is noted here that the emission spectrum was measured in a wavelength range of 300 nm to 950 nm using a quantum efficiency measurement system (trade name: QE-2100, manufactured by Otsuka Electronics Co., Ltd.) at room temperature (25° C.) with an excitation light wavelength of 365 nm, and the internal quantum yield was calculated for a wavelength range of 450 nm to 950 nm. The results thereof are shown in Table 1 and FIG. 1. FIG. 1 shows the relative emission intensity spectrum of the semiconductor nanoparticles of Example 1 that was normalized by maximum emission intensity.

### Example 2

### First Step

A first mixture was obtained by mixing 0.1 mmol of copper (I) ethylxanthate (Cu(EX)), 0.4 mmol of silver ethylxanthate (Ag(EX)), 0.5 mmol of indium acetate (In(OAc)₃), 1.0 mmol of gallium acetylacetonate (Ga(acac)₃), and 0.075 mmol of gallium chloride (GaCl₃) with 100 mL of oleylamine (OLA). This first mixture was heat-treated at 260° C. for 120 minutes with stirring in a nitrogen atmosphere. The thus obtained suspension was allowed to cool and then centrifuged (radius: 146 mm, at 2,800 rpm for 5 minutes), and the resulting precipitate was removed to obtain a dispersion of first semiconductor nanoparticles.

### Second Step

Subsequently, 60 mL of the thus obtained dispersion containing 0.3 mmol of the first semiconductor nanoparticles in terms of nanoparticle concentration was mixed with 9.0 mL of oleylamine containing 0.9 mmol of gallium chloride (GaCl₃) to obtain a second mixture. This second mixture was heat-treated at 270° C. for 120 minutes with stirring in a nitrogen atmosphere. Thereafter, the resulting suspension was cooled to obtain a dispersion of second semiconductor nanoparticles.

For the thus obtained second semiconductor nanoparticles, the results of measuring the emission spectrum in the same manner as in Example 1 are shown in Table 1 and FIG. 1.

### Comparative Example 1

### Synthesis of Semiconductor Nanoparticles

First, 0.02 mmol of copper (II) acetate (Cu(OAc)₂, 0.78 mmol of silver acetate (AgOAc), 0.8 mmol of indium acetate (In(OAc)₃), 2.5 mmol of dodecanethiol (DDT), and 20 mL of oleylamine were mixed, and the resultant was heated to 140° C. in a nitrogen atmosphere. Once the temperature reached 140° C., 600 μL of an oleylamine solution containing 0.4 mmol/L of 1,3-dibutyl-2-thiourea (1,3-dbtu) was added dropwise over a period of 30 minutes using a syringe pump. After the completion of this dropwise addition, the resultant was further heat-treated at 140° C. for 30 minutes. Thereafter, the resulting suspension was cooled to obtain a dispersion of semiconductor nanoparticles.

A mixture was obtained by mixing 2.63 mL of the thus obtained oleylamine dispersion containing 0.03 mmol of semiconductor nanoparticles with 0.067 mmol of gallium acetylacetonate (Ga(acac)₃), 0.067 mmol of 1,3-dimethyl-2-thiourea (1,3-dmtu), and 7.0 ml of oleylamine. This mixture was decompressed at 80° C. for 30 minutes, and subsequently heated to 250° C. at a rate of 25° C./min and then to 280° C. at a rate of 2° C./min. After being heat-treated at 280° C. for 1 minute, the mixture was cooled to obtain a dispersion of semiconductor nanoparticles of Comparative Example 1.

For the thus obtained semiconductor nanoparticles of Comparative Example 1, the results of measuring the emission spectrum in the same manner as in Example 1 are shown in Table 1 and FIG. 1.

TABLE 1

| | Peak | Full width | Band-edge | |
|---|---|---|---|---|
| | emission | at half | emission | Quantum |
| | wavelength | maximum | purity | yield |
| | (nm) | (nm) | (%) | (%) |
| Example 1 | 634 | 90 | 49 | 36 |
| Example 2 | 625 | 63 | 87 | 77 |
| Comparative | 645 | 77 | 61 | 55 |
| Example 1 | | | | |

According to Table 1, in Example 1, semiconductor nanoparticles exhibiting band-edge emission with a peak emission wavelength in a range of 610 nm to 650 nm were obtained by one-pot synthesis; therefore, one-pot synthesis was confirmed to be a more efficient production method than the method of Comparative Example 1. Further, in Example 2, semiconductor nanoparticles exhibiting a higher band-edge emission purity and a higher internal quantum yield were obtained as compared to Comparative Example 1.

The disclosure of Japanese Patent Application No. 2021-126859 (filing date: Aug. 2, 2021) is hereby incorporated by reference in its entirety. All the documents, patent applications, and technical standards that are described in the present specification are hereby incorporated by reference to the same extent as if each individual document, patent application, or technical standard is concretely and individually described to be incorporated by reference.

What is claimed is:

1. A method of producing semiconductor nanoparticles, the method comprising performing a first heat treatment of a first mixture comprising a copper (Cu) salt, a silver (Ag) salt, a salt comprising at least one of indium (In) or gallium (Ga), a first gallium halide, and an organic solvent, to obtain first semiconductor nanoparticles,
wherein at least one of the Cu salt, the Ag salt, or the salt comprising at least one of In or Ga in the first mixture comprises a compound having a bond formed of a metal and sulfur (S).

2. The method of producing semiconductor nanoparticles according to claim 1, wherein, in the first mixture, a content molar ratio of the first gallium halide with respect to a total amount of the Ag salt and the Cu salt is 0.01 to 1.

3. The method of producing semiconductor nanoparticles according to claim 1, wherein a total concentration of the Ag salt and the Cu salt in the first mixture is 0.001 mmol/L to 500 mmol/L.

4. The method of producing semiconductor nanoparticles according to claim 1, wherein the first heat treatment is performed at 200° C. to 320° C.

5. The method of producing semiconductor nanoparticles according to claim 1, wherein the first gallium halide in the first mixture comprises gallium chloride.

6. The method of producing semiconductor nanoparticles according to claim 1, wherein the Cu salt in the first mixture comprises a compound having a Cu—S bond.

7. The method of producing semiconductor nanoparticles according to claim 1, the method further comprising performing a second heat treatment of a second mixture comprising the first semiconductor nanoparticles and a second gallium halide, to obtain second semiconductor nanoparticles.

8. The method of producing semiconductor nanoparticles according to claim 7, wherein, in the second mixture, a molar ratio of the second gallium halide with respect to the first semiconductor nanoparticles is 0.01 to 50.

9. The method of producing semiconductor nanoparticles according to claim 7, wherein the second gallium halide in the second mixture comprises gallium chloride.

10. The method of producing semiconductor nanoparticles according to claim 7, wherein the second heat treatment is performed at 200° C. to 320° C.

11. Semiconductor nanoparticles, comprising:
a first semiconductor comprising copper (Cu), silver (Ag), indium (In), gallium (Ga), and sulfur (S); and
a second semiconductor comprising Ga and S but not substantially containing Ag,
wherein the second semiconductor is arranged in surfaces of one or more of the semiconductor nanoparticles,
wherein the semiconductor nanoparticles exhibit band-edge emission with a peak emission wavelength in a wavelength range of 600 nm to 680 nm when irradiated with a light having a wavelength of 365 nm,
wherein the band-edge emission purity is 60% or higher, and
wherein the internal quantum yield of the band-edge emission is 15% or more.

12. The semiconductor nanoparticles according to claim 11, wherein an emission spectrum of the semiconductor nanoparticles has a full width at half maximum that is 70 nm or less.

13. The semiconductor nanoparticles according to claim 11, wherein surfaces of one or more of the semiconductor nanoparticles are modified with a gallium halide.

14. A light emitting device, comprising:
a light conversion member comprising the semiconductor nanoparticles according to claim 11; and
a semiconductor light emitting element.

15. The light emitting device according to claim 14, wherein the semiconductor light emitting element is an LED chip.
